(19) United States
(12) Patent Application Publication
(10) Pub. No.: US 2014/0055901 A1
(43) Pub. Date: Feb. 27, 2014

(54) SOLID STATE FAULT ISOLATION DEVICES AND METHODS

(71) Applicant: North Carolina State University, Raleigh, NC (US)

(72) Inventors: Woongje Sung, Raleigh, NC (US); Qin Huang, Cary, NC (US); Bantval Jayant Baliga, Raleigh, NC (US)

(73) Assignee: North Carolina State University, Raleigh, NC (US)

(21) Appl. No.: 13/975,970

(22) Filed: Aug. 26, 2013

Related U.S. Application Data
(60) Provisional application No. 61/693,253, filed on Aug. 25, 2012.

(51) Int. Cl. H01L 29/808

(52) U.S. Cl. CPC H01L 29/808
USPC 361/93.9; 257/77; 257/76; 327/566

(57) ABSTRACT

Disclosed herein are solid state fault isolation devices and methods. According to one or more embodiments, a semiconductor current fault controlled device is provided. The device includes a semiconductor substrate of N-type conductivity. The substrate has opposed major surfaces. An anode region of P-type conductivity is formed in one major surface. A P-type buried layer is formed in a first portion of the other major surface. A junction field-effect transistor (JFET) is formed in a second portion of the other major surface. A P-type top layer is formed in the JFET and forms a channel defined by an overlap between the P-type buried layer and the P-type top layer. The channel laterally extends to the semiconductor substrate from a cathode region and being shielded from the anode region.

### CROSS REFERENCE TO RELATED APPLICATION

This application claims the benefit of U.S. patent application No. 61/693,253, filed Aug. 25, 2012 and titled SOLID STATE FAULT ISOLATION DEVICES AND METHODS, the disclosure of which is incorporated herein by reference in its entirety.

### FEDERALLY SPONSORED RESEARCH OR DEVELOPMENT

The technology disclosed herein was made with government support under award number EEC-0812121 awarded by the ERC Program of the National Science Foundation. The United States government may have certain rights in the technology.

### TECHNICAL FIELD

The present disclosure is directed towards a solid state fault isolation device, and more particularly, towards a field controlled diode having a buried layer forming a normally-on junction gate field-effect transistor (JFET) region for forming fault controlled devices and associated fault isolation devices.

### BACKGROUND

Many devices have been designed to protect an electronic circuit from damage caused by a short circuit or power overload. These electronic circuit protection devices should be capable of turning themselves off when a short circuit or power overload is detected. However, conventional devices have slow response times and are expensive to implement. Conventional devices may also suffer from premature device destruction. Additionally, conventional devices may not be configured for fault isolation, thereby allowing identification of the short circuit and appropriate repair.

Accordingly, electronic circuit protection devices that address these disadvantages and others associated with conventional devices are needed.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

Disclosed herein are solid state fault isolation devices and methods. According to an aspect, a semiconductor current fault controlled device is provided. The device includes a semiconductor substrate of N-type conductivity. The substrate has opposed major surfaces. An anode region of P-type conductivity is formed in one major surface. A P-type buried layer is formed in a first portion of the other major surface. A junction field-effect transistor (JFET) is formed in a second portion of the other major surface. A P-type top layer is formed in the JFET and forms a channel defined by an overlap between the P-type buried layer and the P-type top layer. The channel laterally extends to the semiconductor substrate from a cathode region and being shielded from the anode region.

According to an aspect, the substrate is formed from a silicon carbide structure.

According to an aspect, the substrate is formed from a gallium nitride structure.

According to an aspect, a method may limit current and provide fault detection. The method may include providing an electronic circuit. Further, the method may include electrically connecting any of the devices in accordance with the present subject matter to nodes of the electronic circuit for limiting current between the nodes and for fault detection.

According to an aspect, a method may include providing a power distribution system. The method may also include implementing one of more of any of the devices in accordance with the present subject matter in the power distribution system.

### BRIEF DESCRIPTION OF THE DRAWINGS

The foregoing summary, as well as the following detailed description of various embodiments, is better understood when read in conjunction with the appended drawings. For the purposes of illustration, there is shown in the drawings exemplary embodiments; however, the presently disclosed subject matter is not limited to the specific methods and instrumentalities disclosed. In the drawings:

FIG. 1 illustrates a diagram of a conventional planar gate type field controlled diode (FCD) in accordance with embodiments of the present subject matter;

FIG. 2 illustrates a diagram of an asymmetric FCD in accordance with embodiments of the present subject matter;

FIG. 3 illustrates a schematic view of a power distribution system in accordance with embodiments of the present subject matter;

FIG. 4 depicts a chart that compares various options for providing fault isolation devices (FID) with the FCD disclosed herein;

FIG. 5 depicts a chart that compares various topologies to implement an FID as disclosed herein;

FIG. 6 illustrates a wiring schematic having FID 1-3 in which Iₛₐₜ₁=Iₛₐₜ₂=Iₛₐₜ₃ and associated I-V data in accordance with embodiments of the present subject matter;

FIG. 7 illustrates a wiring schematic having FID 1-3 in which Iₛₐₜ₃>Iₛₐₜ₂>Iₛₐₜ₁ and associated I-V data in accordance with embodiments of the present subject matter;

FIG. 8 illustrates a graph that compares J-V characteristics of FID candidate devices in accordance with embodiments of the present subject matter;

FIGS. 9A and 9B depicts graphs of forward blocking capabilities of the conventional planar gate type FCD (FIG. 9A) and an example FCD (FIG. 9B) in accordance with embodiments of the present subject matter;

FIGS. 10A and 10B illustrate schematics of a conventional gating circuit (FIG. 10A) and a cascode gating circuit (FIG. 10B) for an FCD in accordance with embodiments of the present subject matter;

FIG. 11 illustrates a graph showing the expectation of the short circuit current in the fault condition for an FCD in accordance with embodiments of the present subject matter;

FIG. 12 illustrates a graph showing an example of transient response to the fault of an FCD gated with cascode circuit in accordance with embodiments of the present subject matter;

FIG. 13 illustrates a graph showing the trade-off between on-state voltage drops and short circuit capability in accordance with embodiments of the present subject matter;

FIG. 14 illustrates a graph showing turn off of the FCD using the cascode gating circuit in accordance with embodiments of the present subject matter;

FIGS. 15A and 15B illustrates schematic diagrams of a power distribution line having two loads and the initial condition of simulation in accordance with embodiments of the present subject matter;

FIG. 16 illustrates a chart showing simulated voltage response of FIDs to a fault in accordance with embodiments of the present subject matter; and

FIGS. 17A and 17B are charts showing effects of distance and load on voltage response of FIDs to the fault in accordance with embodiments of the present subject matter.

### DETAILED DESCRIPTION

While the disclosure of the technology herein is presented with sufficient details to enable one skilled in this art to practice the presently disclosed subject matter, it is not intended to limit the scope of the disclosed technology. It is contemplated that future technologies may facilitate additional embodiments of the presently disclosed subject matter as claimed herein. Moreover, although the term “step” may be used herein to connote different aspects of methods employed, the term should not be interpreted as implying any particular order among or between various steps herein disclosed unless and except when the order of individual steps is explicitly described.

Disclosed herein is a field controlled diode (FCD) and associated solid-state fault isolation devices (FIDs) for short circuit protection applications in power distribution systems. Exemplary performance characteristics of the FID are to have a low on-state loss and a strong short circuit safe operating area (SCSOA). In accordance with embodiments, a 15 kV 4H—SiC FCD with a p⁺ buried layer can be provided to provide an improved trade-off between the on-state forward voltage drop and the saturation current. In accordance with embodiments, the FCD can clear the fault by turning itself off.

In accordance with embodiments, a gating technique may be used to influence the transient behavior of the FCD in a fault condition. In an experiment, it was found that the cascode gating circuit with a low voltage silicon n-MOSFET was more suitable for enhanced SCSOA than conventional gating techniques. Non-iso-thermal 2D device simulation may be used to verify the operation of an FCD.

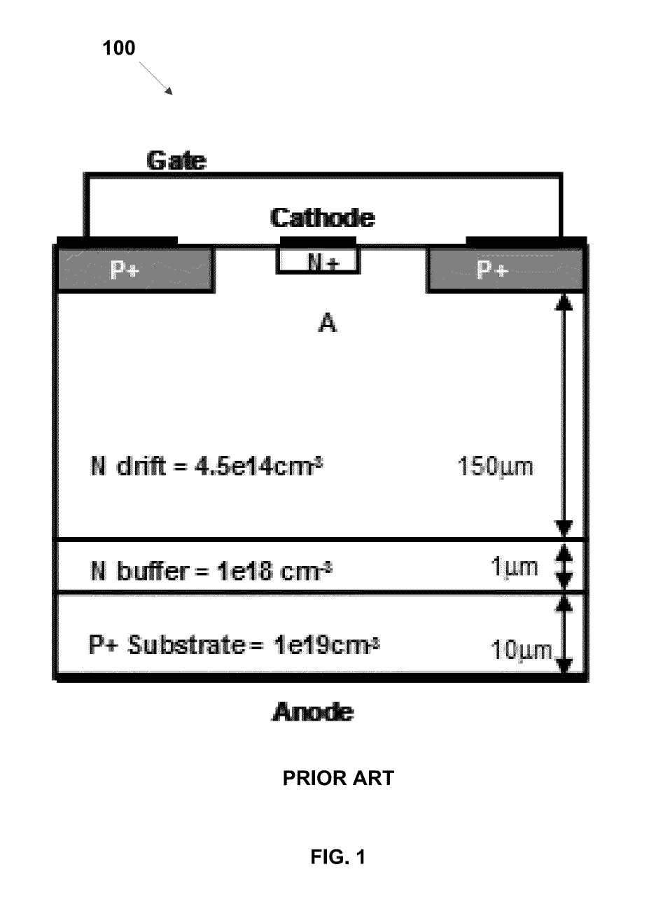

FIG. 1 illustrates a conventional planar type FCD 100. In the conventional planar gate type FCD, when the anode voltage increases, the potential barrier formed by the adjacent p⁺/N-drift junctions can be lowered, thereby allowing significant current flow from the cathode to the anode.

An FID configured to protect loads in a power distribution system may be configured to block about 15 kV and to have a low saturation current (i.e., strong short circuit capability) while maintaining a low forward voltage drop due to its normally-on operation.

Silicon carbides, such as 4H—SiC and the like, can provide up to ten times higher critical electric field, three times wider band gap, and three times higher thermal conductivity when compared to silicon. The superior material properties of 4H—SiC can enable the development of a solid-state FID, which can isolate a fault in an electrical circuit much faster than a conventional mechanical circuit breaker.

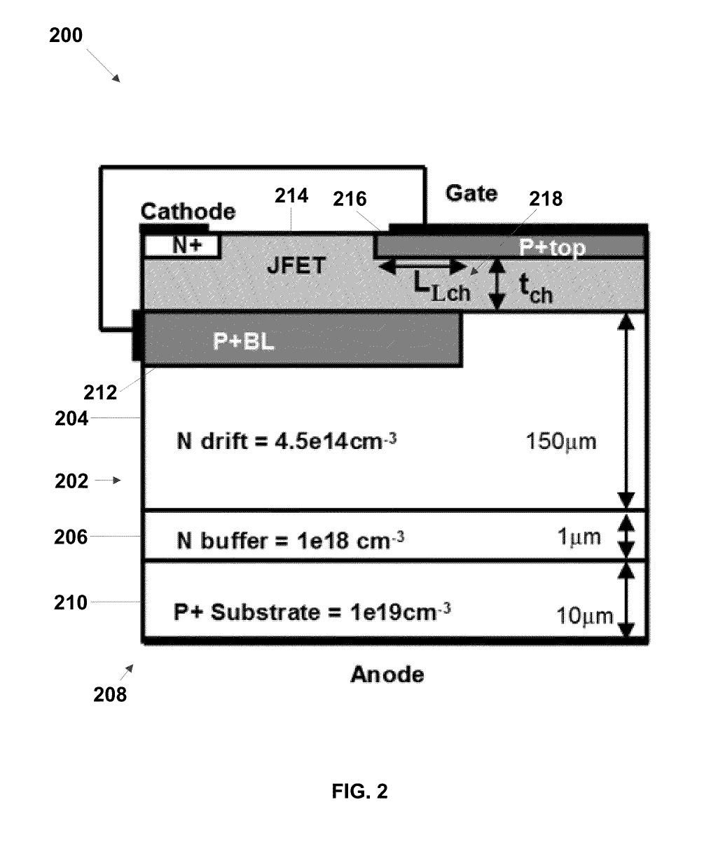

In accordance with embodiments, a structure of a 4H—SiC FCD is disclosed herein which includes the p⁻ buried layer (p⁺ BL) forming a normally-on JFET region together with the p⁺ top layer such as that shown in FIG. 2, which illustrates a diagram of an example asymmetric FCD 200 in accordance with embodiments of the present subject matter. Referring to FIG. 2, the FCD 200 includes a substrate, generally designated 202, of N-type conductivity. Particularly, the FCD 200 includes an N-type drift layer 204 and an N-type buffer layer 206, although it should be understood that any suitable types of layers having any suitable thicknesses may be utilized. In an example, the FCD may be a symmetric device having a 247 μm thick drift layer without a buffer layer.

The FCD 200 may include an anode region, generally designated 208, of P-type conductivity that is attached to a bottom surface of the buffer layer 206. The anode region 208 may include a P-type substrate 210. In this example, the P-type substrate 210 has a thickness of 247 μm, although it may be of any suitable thickness. Further, the anode region 208 may include one or more other suitable layers of any suitable thicknesses.

A P-type buried layer 212 may be buried in a side of the substrate 202 that opposes the anode region 208. The buried layer 212 may be of any suitable type, size, and shape.

The FCD 200 includes a JFET 214 positioned on a top surface of the buried layer 212 and the N-type substrate 202 as shown. The JFET 214 may be of any suitable type, size, and shape. Further, the FCD 200 may include a P-type layer 216 positioned in the JFET 214 and that, when active, forms a channel, generally designated 218, in the JFET 214 that extends into the JFET 214 between the P-type layer 216 and the P-type buried layer 212. An example advantage of the FCD 200 is that the JFET region may shield the channel 218 from the anode side.

As a fault isolation device, the FCD disclosed herein has several advantages over other switching devices such as MOSFETs and IGBTs. For example, the FCD may be configured to block 15 kV while having low on-state loss. 4H—SiC is an exemplary selection of material because it has an improved BV versus on-state loss trade-off than the devices in silicon.

In accordance with embodiments, an FCD may use conductivity modulation to lower the on-state forward voltage drop. Since a switching event occurs when there is a fault, low switching energy loss may not be critical for this application. Thus, a bipolar device may, in some instances, be a better option than a unipolar device.

In accordance with embodiments, an FCD may be configured to control the saturation current with low forward voltage drops. By having an embedded JFET structure in the FCD, it may be possible to control the saturation current level by the JFET channel length, thickness, and doping concentration.

In accordance with embodiments, an FCD may be a normally-on type device, so the gate is shorted to the cathode during normal operation

It is noted that the fabrication of the FCD may not be as complicated as that of MOS gated power devices. The p+ buried layer can be implemented by high energy implants or by the epitaxial re-growth process.

In accordance with embodiments, the FCD is configured to detect a voltage increase to obtain a fault signal and then isolate the short circuit or power overload causing the fault signal from the rest of the grid.

The FCD illustrated in FIG. 2 may be characterized in that the channel 218 extends from the depletion layer from p⁺ buried layer 212, and p⁻ top layer 216 into the JFET region. As illustrated in FIG. 2, channel thickness is denoted by t_{ch} and channel length by L_{ch}. In accordance with embodiments, channel thickness t_{ch} may be between about zero (0) and about one (1) μm, or any other suitable thickness. In accordance with embodiments, L_{ch} may be about 2 μm, or any other suitable length.

As illustrated in FIG. 2, a symmetric device may have a 247 μm thick drift layer without a buffer layer. While disclosed herein as a silicon carbide material, the FCD is not so limited and may be formed from any appropriately configured material.

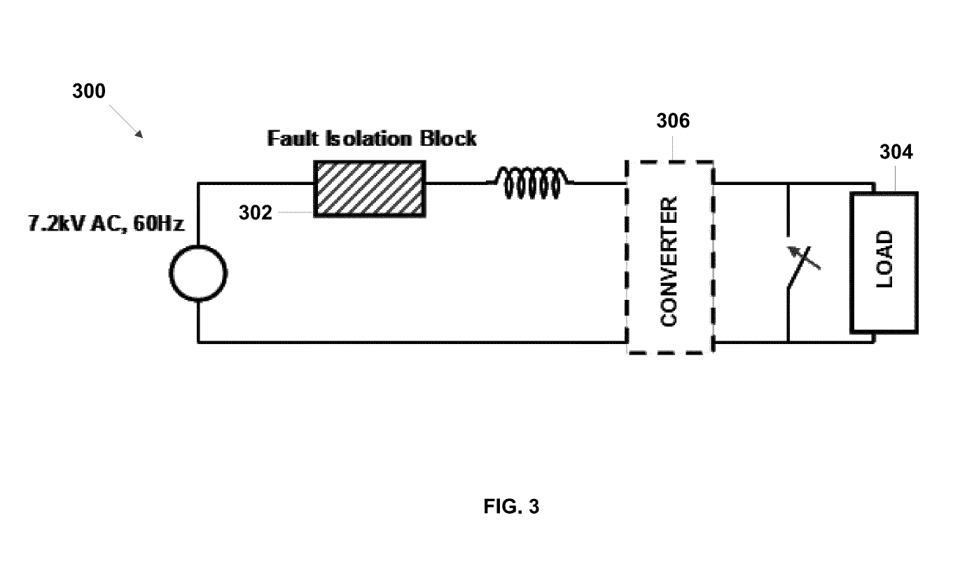

FIG. 3 illustrates a schematic view of a power distribution system 300 in accordance with embodiments of the present subject matter. The system 300 may utilize an FCD 302 as disclosed herein. When a fault shorts the load 304, the current from the converter 306 can try to increase. Since the power between the input and output side of the converter 306 should be balanced, the input current flowing into the converter 306 can also increase, which can damage the converter 306. Therefore, the FCD 302, operating as a fault isolation device, can be configured to limit the current and to isolate the converter 306 by turning itself off.

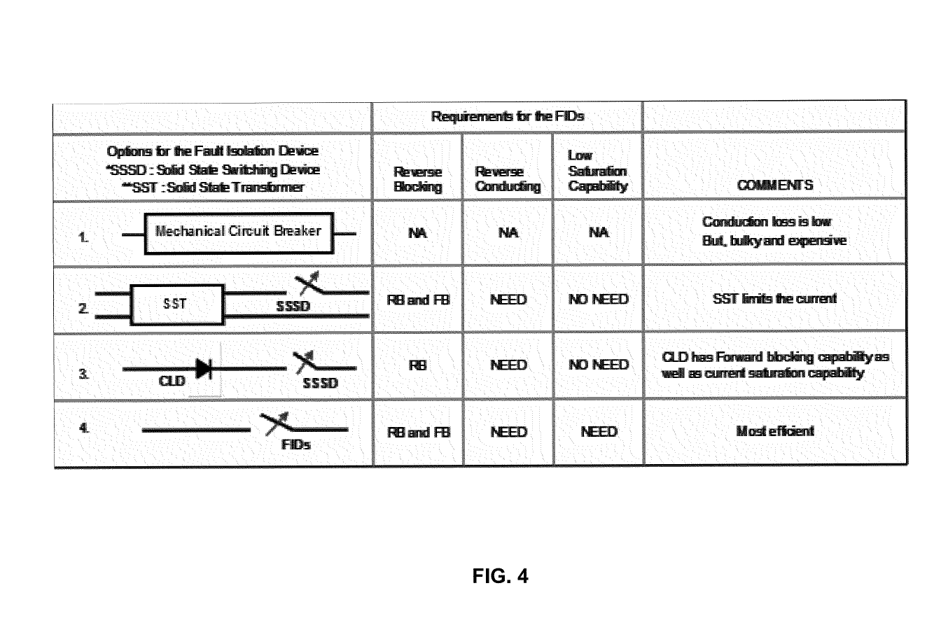

FIG. 4 summarizes several options for an FID disclosed herein and compares the fault isolation device (FID) to conventional options. The traditional way to isolate a fault is to use a mechanical circuit breaker (option 1). When a solid state transformer (SST) is used for the converter block, the SST can inherently limit the current, and the FID is relegated to isolating the fault (option 2). By configuring the current limiting device (CLD) in series with the FID, the current limiting function as well as fault isolation can be achieved (option 3). An efficient way to achieve both current limiting and fault isolation functions is to develop a FID that has a strong current limiting function (option 4). For example, it can take about 150 ms (9 cycle/60) for the conventional mechanical circuit breaker to respond to the fault while the FID needs in the range of 10 milliseconds or less to detect the fault and isolate it.

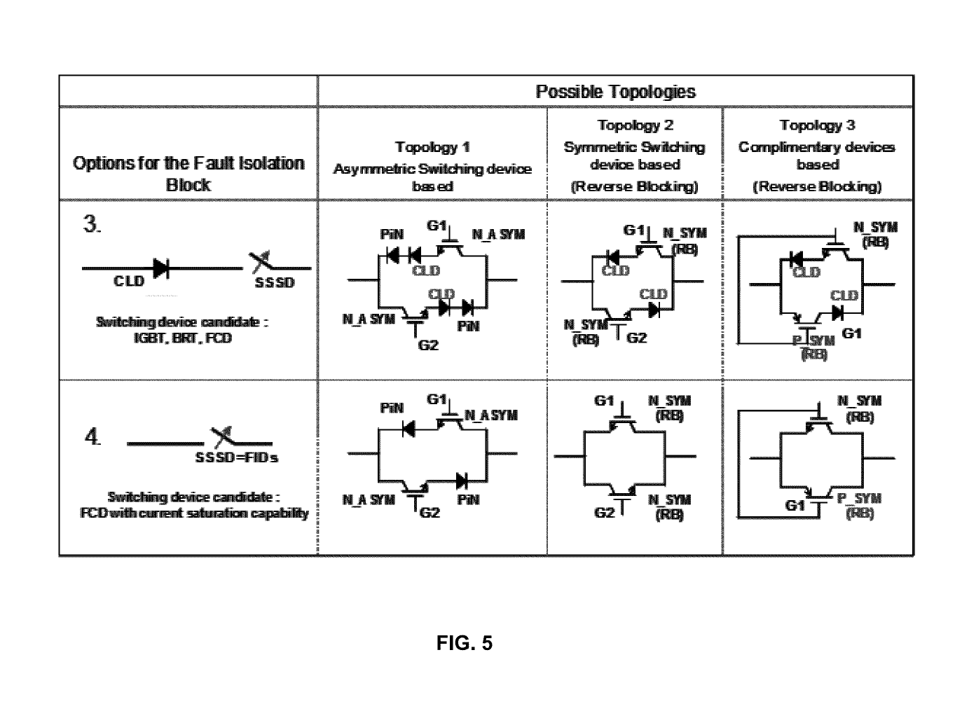

Possible topologies to implement an FID as disclosed herein are summarized in FIG. 5. Forward/reverse conducting, and forward/reverse blocking capabilities can be attained by configuring solid-state devices as shown in each topology. It should be noted that the additional conduction loss is present in option 3 due to the CLD's forward voltage drop, when compared with option 4. Therefore, it is necessary to develop a switching device which is able to lower the saturation current while maintaining a low on-state forward voltage.

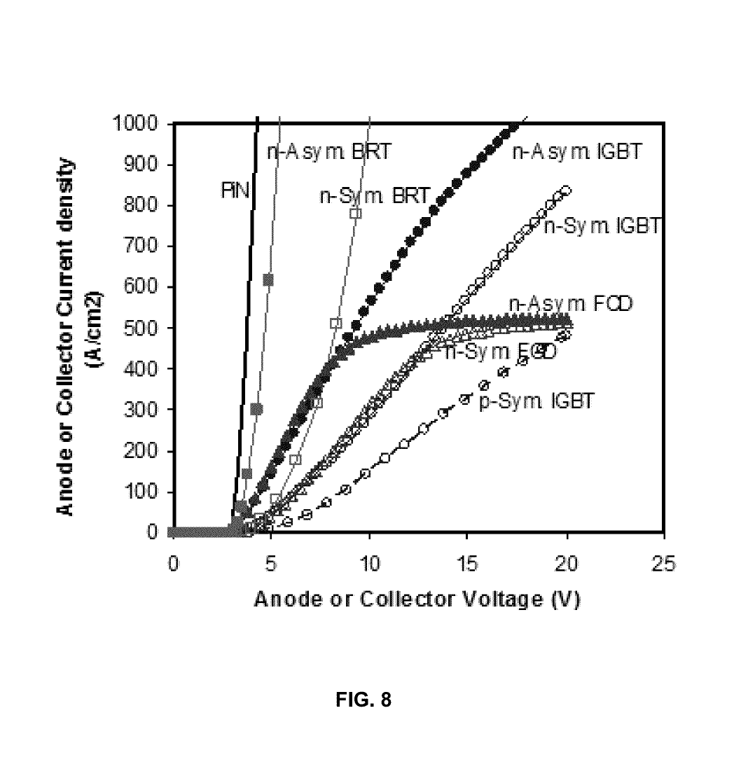

FIG. 8 compares i-V characteristics of IGBTs, BRTs, and FCDs. Compared to the IGBTs, the FCDs disclosed herein show lower forward voltage drop as well as lower saturation current.

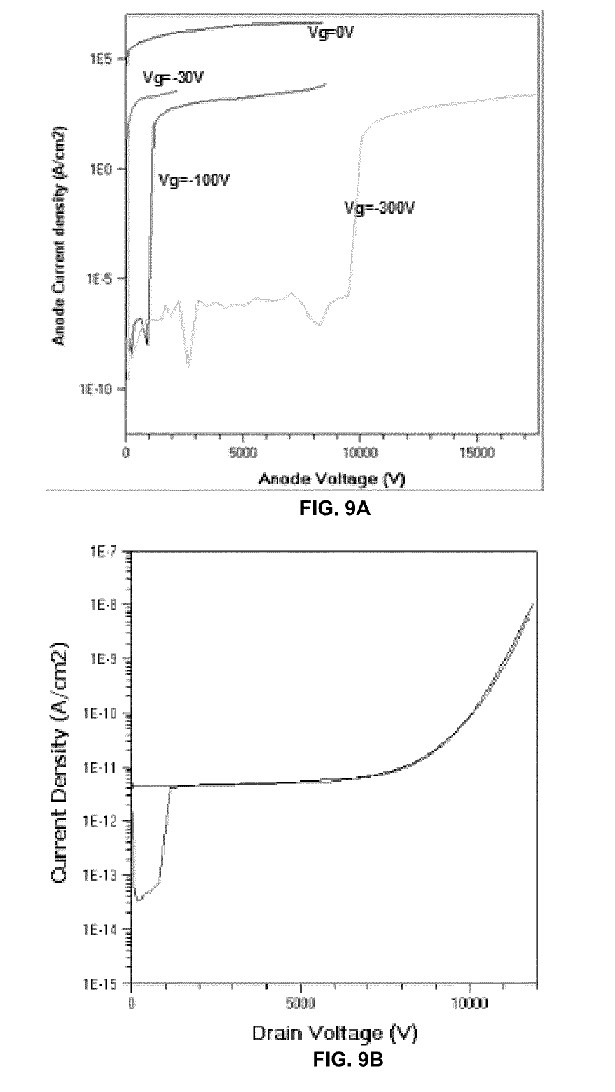

FIGS. 9A and 9B depicts graphs of forward blocking capabilities of the conventional planar gate type FCD (FIG. 9A) and an example FCD (FIG. 9B) in accordance with embodiments of the present subject matter. The graphs compare the forward blocking characteristics of the conventional FCD, as illustrated in FIG. 9A, and an FCD as disclosed herein and illustrated in FIG. 9B. The blocking gain (V_{AK}/V_{g}) of 1000 can be achieved in the FCD while that of conventional planar gate type FCD is only <30.

### Gating Techniques to Turn Off FIDs

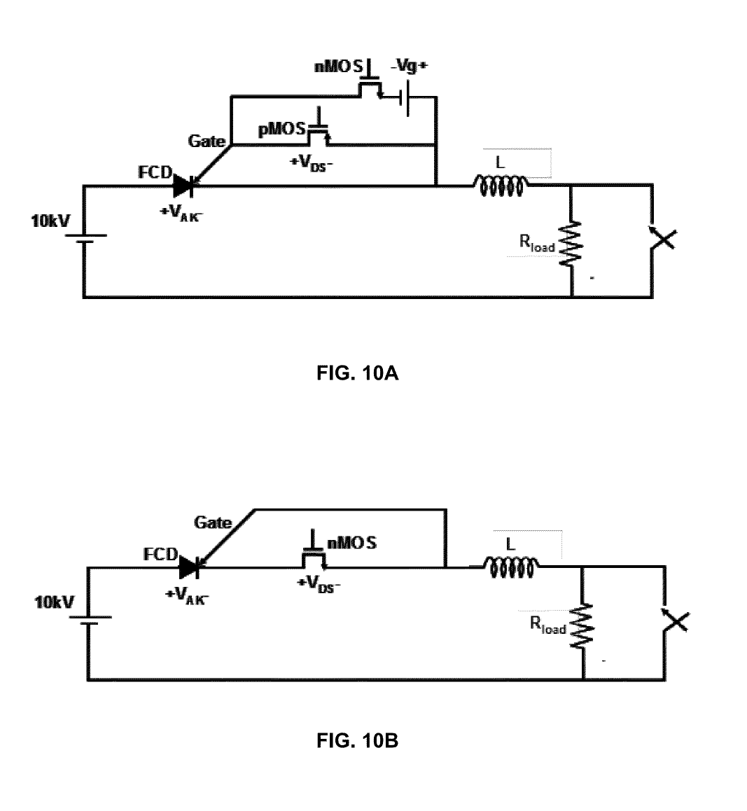

In an experiment, two different gating techniques with portions were compared to turn off the FCD in a fault condition. In the conventional gating circuit as illustrated in FIG. 10A, a low voltage silicon p-MOSFET was connected to the gate of the FCD in the normal on-state and short circuit condition. In order to turn off the FCD, and thereby isolate the fault, sufficient negative bias can be applied to the gate terminal to shut off the channel by extending the depletion layer from p+bl, and p+top into the JFET region. This may be done by, for example, turning off the p-MOSFET and by turning on the n-MOSFET that is connected to the negative gate source (Vg) in series. It should be noted that the low voltage silicon switching device connected to the gate of the FCD in normal operation is supposed to block negative gate bias during the turn-off event. Therefore, a p-MOSFET was used for this experiment and it is in synchronous rectification mode (i.e., first quadrant) under normal operation. In the cascode gating circuit, a low voltage silicon n-MOSFET is connected to the cathode of the FCD. The current flow through the FCD can be stopped by turning off the n-MOSFET.

FIGS. 10A and 10B illustrate schematics of conventional gating circuit (FIG. 10A) and the cascode gating circuit (FIG. 10B) for the FCD. In a fault condition, V_{DS} increases as the load current is increased. The fault can be isolated by turning on the n-MOSFET in the conventional gating circuit and by turning off the n-MOSFET in the cascode gating circuit.

When the load is shorted in a fault condition, the load current increases, but is limited by the saturation current of the FCD. The current increase in the faulted circuit results in an increase of the drain-source voltage (V_{DS}) of the Si MOSFETs.

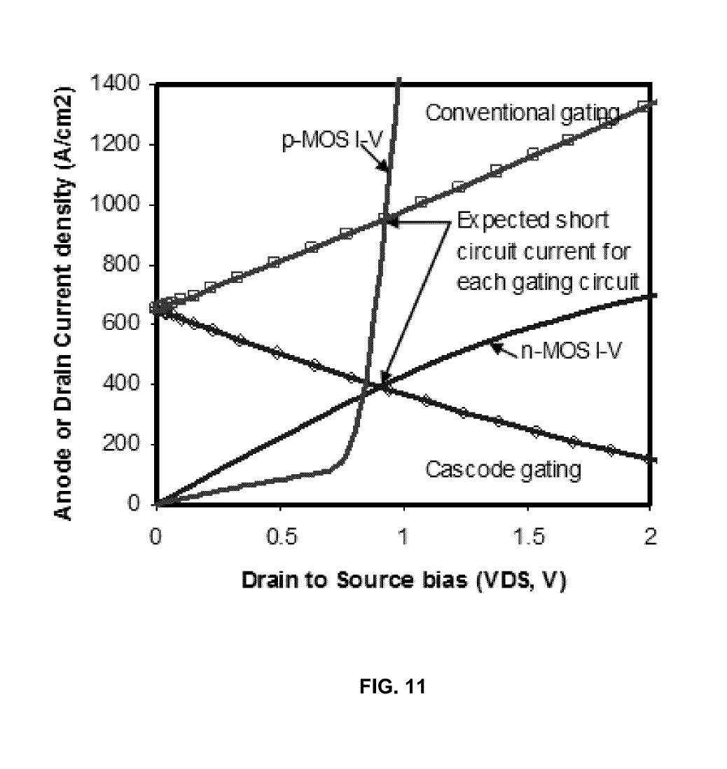

In a first configuration, the V_{DS} is applied to the gate (p⁺ top and p⁺ BL) in the conventional gating circuit. Both p⁺ BL/n JFET and p⁺ top/n JFET junctions are forward biased and therefore, the depletion layers of each junction shrink and produce higher saturation current in the FCD. In the second configuration (cascode gating), since the V_{DS} is connected to the n⁺ cathode, the depletion layer formed by each junction extends toward each other junction thereby lowering the saturation current of the FCD. As a result, the short circuit current converges to a value where the i-V of the MOSFET crosses the saturation current of the FCD corresponding to the V_{DS} as illustrated in FIG. 11. As illustrated in FIG. 11, a longer short circuit capability (SC SOA) may be achieved by using the cascode gating circuit rather than the conventional gating circuit.

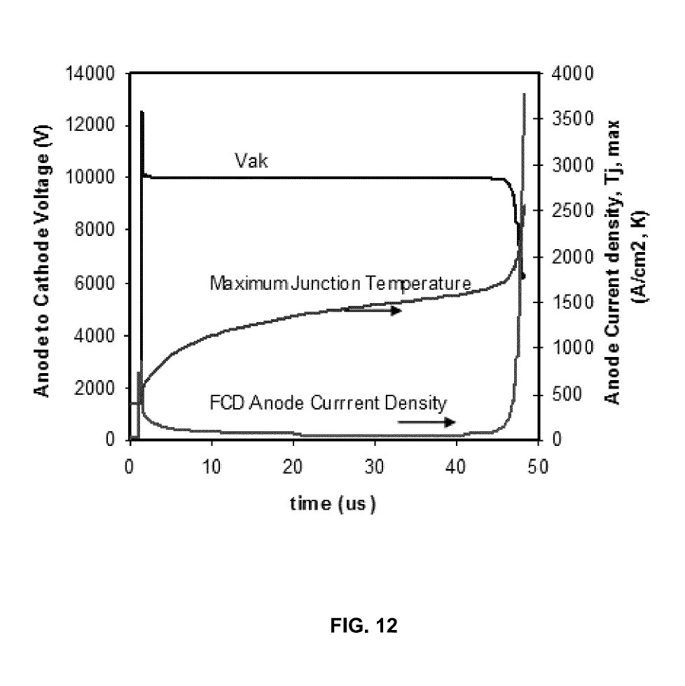

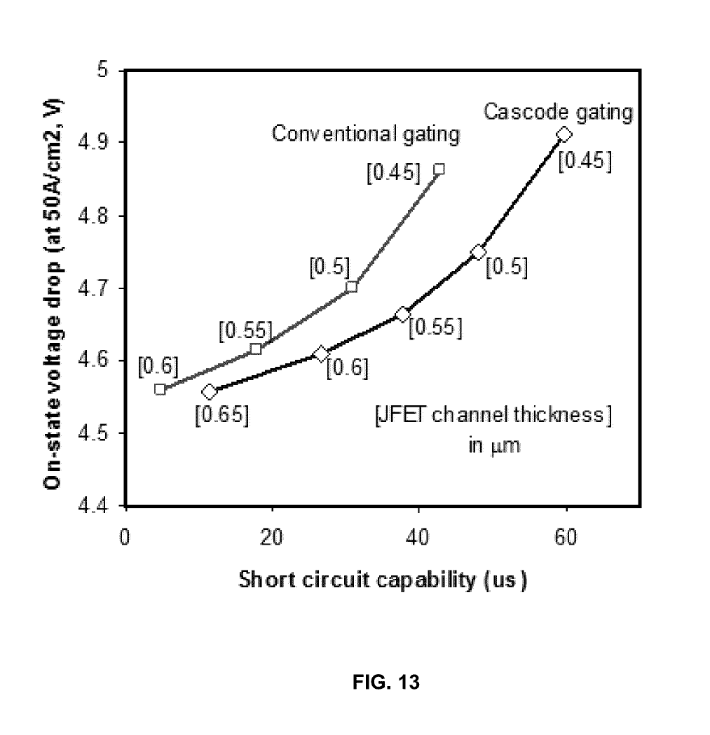

To examine the trade-off between on-state forward voltage drops and the short circuit capability, transient responses to the short circuit using both gating techniques were studied by the non-iso thermal device simulation. FIG. 12 illustrates a graph showing an example of transient response to the fault of the FCD gated with the cascode circuit in accordance with embodiments of the present subject matter. In this simulation, the load is shorted at 1 μs. As illustrated, the anode current and the junction temperature abruptly increase after the fault. As the junction temperature increases, the intrinsic carrier density also increases, becoming similar to the background doping concentration causing the built-in potential to reduce to zero. The temperature at which the built-in potential collapses is defined as the critical temperature; upon reaching this temperature the device starts to undergo thermal runaway. The time for the junction temperature to reach the critical temperature of the corresponding material can be defined as short circuit capability. From this non-iso thermal transient simulation, the short circuit capability in a given FCD structure using different gating techniques can be calculated. The trade-off between on-state voltage drops and short circuit capability, as illustrated in FIG. 13, shows that the cascode gated FCD with low voltage Si n-MOSFET provides a further enhanced SCSOA than the conventional gated one. It should be noted that the cascode gating circuit produces additional voltage drop during normal operation. However, because the blocking capability of the Si MOSFETs is determined by the pinch off voltage of the FCD, a low voltage rated (<30V) Si MOSFET can be used, for which forward voltage drop is negligible compared to that of the 15 kV 4H—SiC FCD.

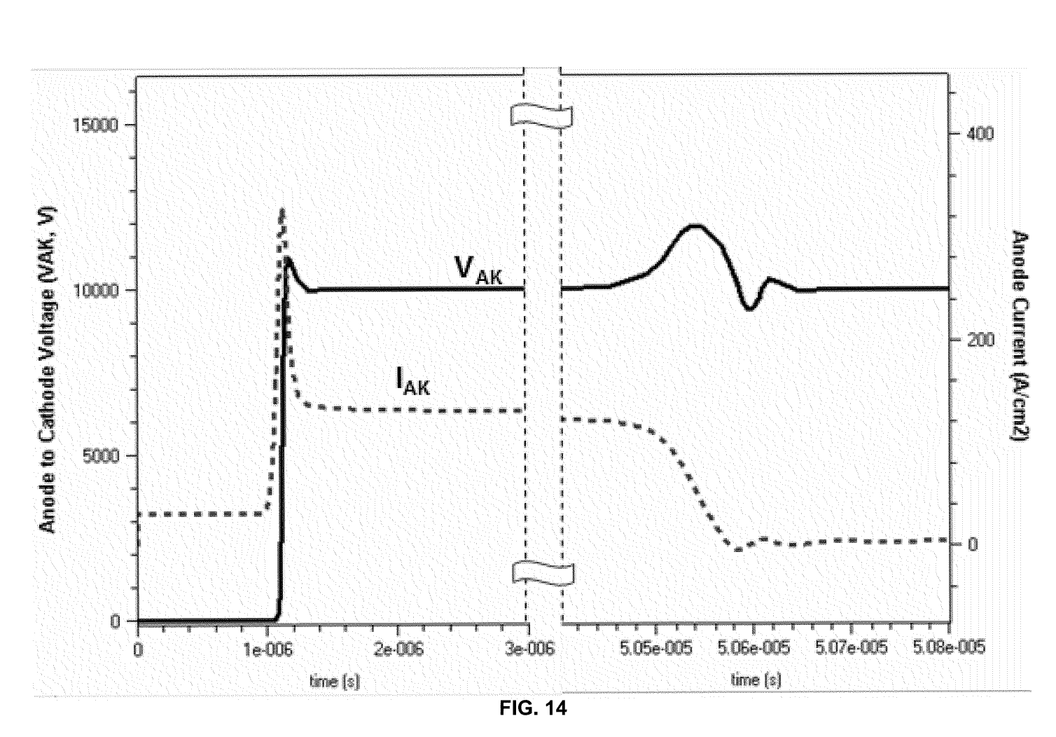

The turn off of the FCD was also verified by the non-iso thermal transient simulation. FIG. 14 illustrates a graph showing the transient response to the fault of the FCD having JFET channel thickness of 0.45 μm. The short circuit capability of this FCD structure using the cascode gating circuit is about 60 μs as illustrated in the graph of FIG. 13. The load is shorted at a time of 1 μs and the n-MOSFET is turned off at 50 us in this simulation. L=1 pH is used. FIG. 14 illustrates verification that the FCD can be turned off using the cascode gating approach and the turn-off time is about 100 ns.

### Application of Fault Isolation Devices

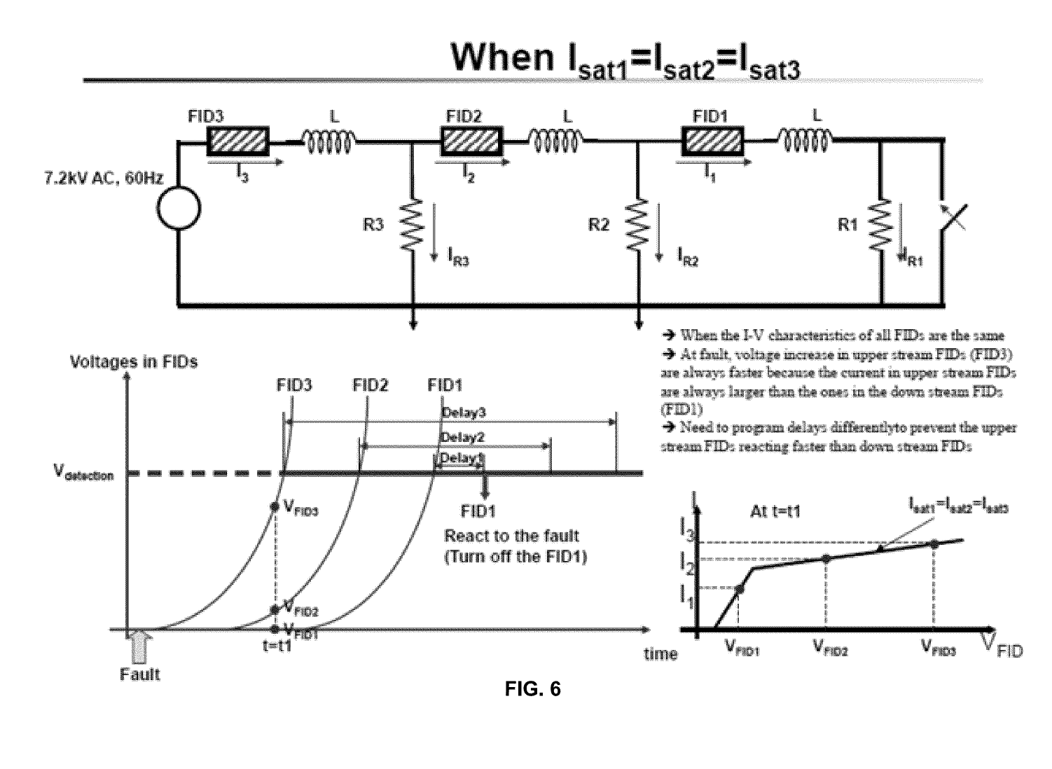

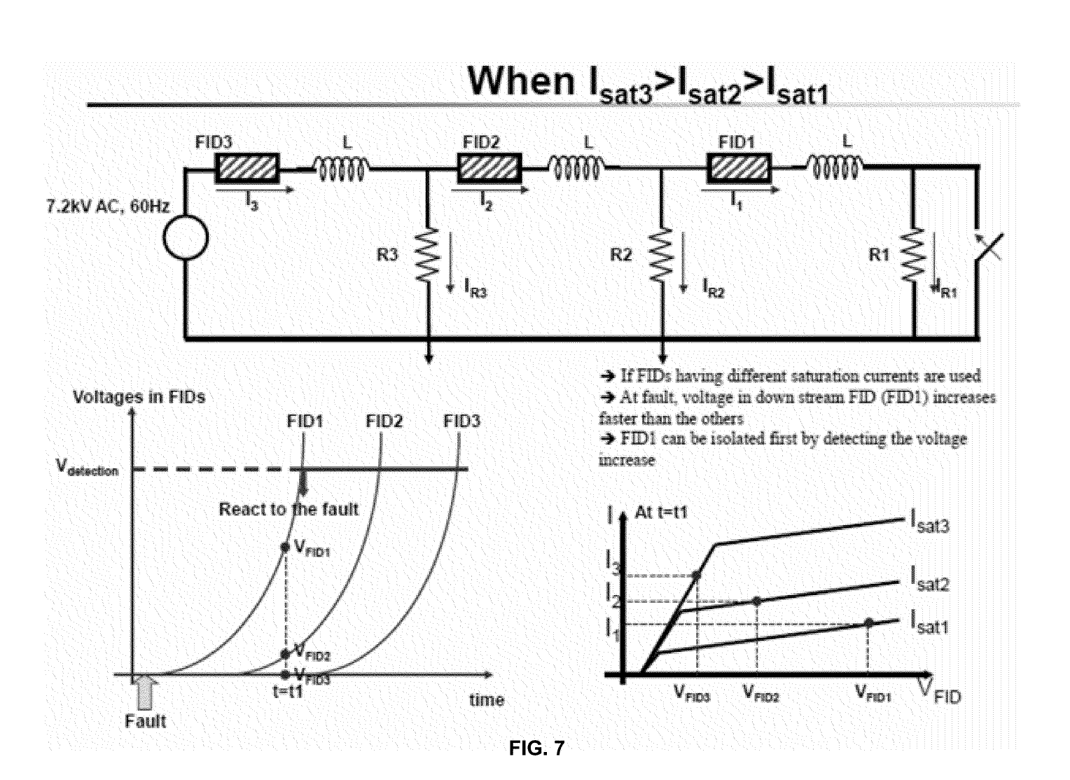

The FCD may also have applications as an FID. This application is also simulated by configuring a simple power distribution system having two loads, such as that which is illustrated in FIGS. 6 and 7, with supply voltage of 7.2 kV. FIG. 6 illustrates a wiring schematic having FID 1, 2, and 3 in which Isat₁ =Isat₂=Isat₃ and associated I-V data for the schematic. FIG. 7 illustrates a wiring schematic having FID1-3 in which Isat₁>Isat₂>Isat₃ and associated i-V data for the schematic. When the power line is shorted, the line current increases (I₂, and thus I₁). As a result, the voltage between each FIDs will increase following the i-V characteristics of the FCD as illustrated in FIG. 6. It should be noted that voltage increase at FID2 is always faster than that of FID1 since current I₂ is larger than I₁. As illustrated in FIG. 7, when the power line is shorted, the voltage between each FIDs will increase following the I-V characteristics of the FCD as illustrated in FIG. 7. The voltage in the downstream FID (FID 1) increases faster than that of FID 2 and FID 3. FID 1 can be isolated first by detecting the voltage increase.

By detecting the voltage increase of the FIDs, the line where the faults happen can be disconnected by turning off the FIDs. However, it is desired to isolate the line downstream of the fault and the line upstream to remain connected. To address this problem, to prevent the upstream FIDs, such as FID2 illustrated in FIGS. 6 and 7, from reacting faster than the downstream FIDs, such as FID1 illustrated in FIGS. 6 and 7, a different delay for each FID may be programmed into the device's control circuitry. In this way, the FIDs can be configured for secure operation of fault isolations.

One of the advantages of an FCD incorporating an FID as disclosed herein includes the advantage being that it about 150 ms (9 cycle/60) for a conventional mechanical circuit breaker to respond to a circuit fault while the FID disclosed herein may be capable of detecting and responding to a fault in the range of 10 milliseconds or less. Further, the FCD incorporating an FID as disclosed herein may be used for DC AND AC power distribution systems.

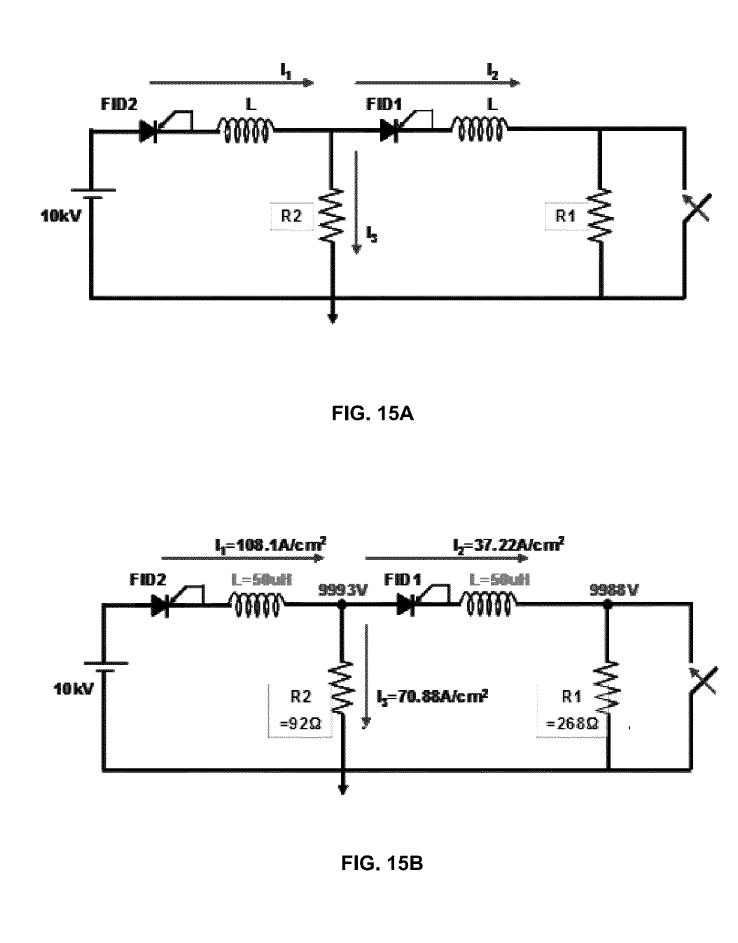

FIGS. 15A and 15B illustrates schematic diagrams of a power distribution line having two loads and the initial condition of simulation in accordance with embodiments of the present subject matter.

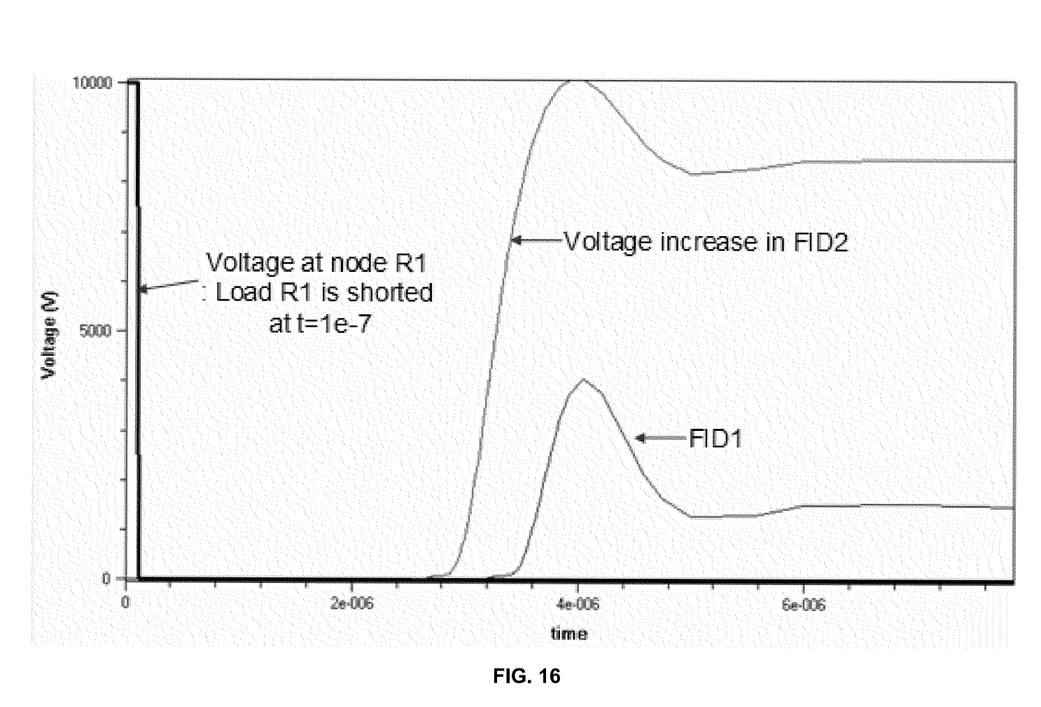

FIG. 16 illustrates a chart showing simulated voltage response of FIDs to a fault in accordance with embodiments of the present subject matter. R1 is shorted at t=0.1 μs.

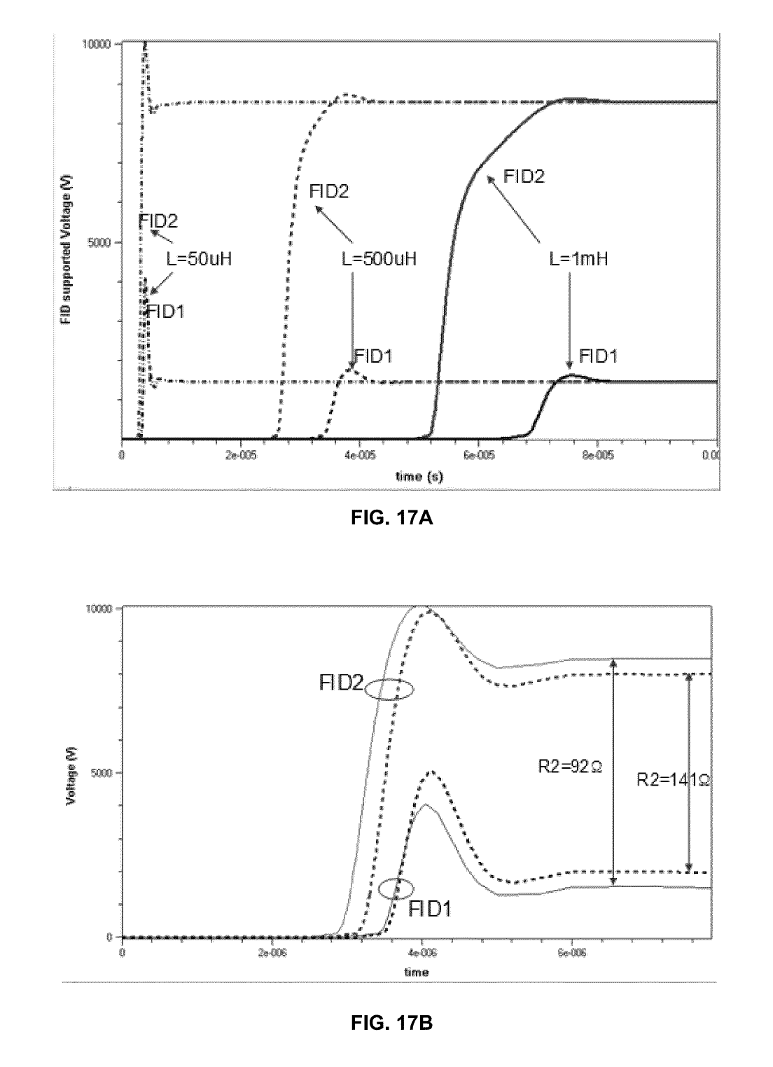

FIGS. 17A and 17B are charts showing effects of distance and load on voltage response of FIDs to the fault in accordance with embodiments of the present subject matter.

For purposes of the description herein, it is understood that when a component such as a layer or substrate is referred to herein as being deposited or formed “on” another component, that component can be directly on the other component or, alternatively, intervening components (for example, one or more buffer or transition layers, interlayers, electrodes or contacts) can also be present. Furthermore, it is understood that the terms “disposed on” and “formed on” are used interchangeably to describe how a given component is positioned or situated in relation to another component. Therefore, it will be understood that the terms “disposed on” and “formed on” do not introduce any limitations relating to particular methods of material transport, deposition, or fabrication.

The various components described herein can be formed by any suitable techniques. For example, components can be formed by sputtering, CVD, or evaporation. Conventional lithographic techniques can be employed in accordance with micromachining of the invention described below. Accordingly, basic lithographic process steps such as photoresist application, optical exposure, and the use of developers are not described in detail herein. Similarly, generally known etching processes can be employed to selectively remove material or regions of material. An imaged photoresist layer is ordinarily used as a masking template. A pattern can be etched directly into the bulk of a substrate, or into a thin film or layer that is then used as a mask for subsequent etching steps. The type of etching process employed in a particular fabrication step (e.g., wet, dry, isotropic, anisotropic, anisotropic-orientation dependent), the etch rate, and the type of etchant used will depend on the composition of material to be removed, the composition of any masking or etch-stop layer to be used, and the profile of the etched region to be formed. As examples, poly-etch (HF:HNO₃:CH₃ COOH) can generally be used for isotropic wet etching. Hydroxides of alkali metals (e.g., KOH), simple ammonium hydroxide (NH₄ OH), quaternary (tetramethyl) ammonium hydroxide ((CH₃)₄ NOH, also known commercially as TMAH), and ethylenediamine mixed with pyrochatechol in water (EDP) can be used for anisotropic wet etching to fabricate V-shaped or tapered grooves, trenches or cavities. Silicon nitride is typically used as the masking material against etching by KOH, and thus can used in conjunction with the selective etching of silicon. Silicon dioxide is slowly etched by KOH, and thus can be used as a masking layer if the etch time is short. While KOH will etch undoped silicon, heavily doped (p++) silicon can be used as an etch-stop against KOH as well as the other alkaline etchants and EDP. Silicon oxide and silicon nitride can be used as masks against TMAH and EDP. The preferred metal used to form contacts and interconnects in accordance with the invention is gold and its alloys. Commonly known wet etchants can be used to etch materials such as copper, gold, silicon dioxide, and secondary materials such as the adhesion and barrier materials. It will be appreciated that electrochemical etching in hydroxide solution can be performed instead of timed wet etching. Dry etching techniques such as plasma-phase etching and reactive ion etching (RIE) can also be used to remove silicon and its oxides and nitrides, as well as various metals. Deep reactive ion etching (DRIE) can be used to anisotropically etch deep, vertical trenches in bulk layers. Silicon dioxide is typically used as an etch-stop against DRIE, and thus structures containing a buried silicon dioxide layer, such as silicon-on-insulator (SOI) wafers, can be used according to the methods of the invention as starting substrates for fabrication. An alternative patterning process to etching is the lift-off process as known to those of skill in the art.

Features from one embodiment or aspect may be combined with features from any other embodiment or aspect in any appropriate combination. For example, any individual or collective features of method aspects or embodiments may be applied to apparatus, system, product, or component aspects of embodiments and vice versa.

While the embodiments have been described in connection with various embodiments shown in the various figures, it is to be understood that other similar embodiments may be used or modifications and additions may be made to the described embodiment for performing the same function without deviating therefrom. Therefore, the disclosed embodiments should not be limited to any single embodiment, but rather should be construed in breadth and scope in accordance with the appended claims.

1-13. (canceled)

14. A device comprising:
an N-type substrate including first and second surfaces;
a P-type anode region being attached to the first surface of the N-type substrate;
a P-type buried layer positioned within the second surface of the N-type substrate;
a junction field-effect transistor (JFET) attached to a surface of the P-type buried layer and the second surface of the N-type substrate; and
a P-type layer positioned in the JFET and that, when active, forms a channel in the JFET that extends into the JFET between the P-type layer and the P-type buried layer.

15. The device of claim 14, wherein the N-type substrate is made of one of silicon carbide and gallium nitride.

16. The device of claim 14, wherein a thickness of the channel is between about 0 and about 1 μm.

17. The device of claim 14, wherein a length of the channel is about 2 μm.

18. The device of claim 14, wherein the JFET shields the channels from the P-type anode region.

19. The device of claim 14, wherein the N-type substrate includes an N-type drift layer.

20. The device of claim 19, wherein the N-type substrate include an N-type buffer layer.

21. The device of claim 14, wherein the N-type drift layer has a thickness of about 150 μm, and wherein the N-type drift layer has a thickness of about 1 μm.

22. The device of claim 14, wherein the P-type layer is electrically connected to the P-type buried layer.

23. The device of claim 14, further comprising an N-type layer positioned in the JFET to form a cathode.

24. The device of claim 23, wherein a portion of the JFET separates the N-type layer and the P-type layer.

25. A device comprising:
a P-type substrate including first and second surfaces;
a N-type anode region being attached to the first surface of the P-type substrate;
a P-type buried layer positioned within the second surface of the P-type substrate;
a junction field-effect transistor (JFET) attached to a surface of the P-type buried layer and the second surface of the P-type substrate; and
a P-type layer positioned in the JFET and that, when active, forms a channel in the JFET that extends into the JFET between the P-type layer and the P-type buried layer.

26. The device of claim 25, wherein the P-type substrate is made of one of silicon carbide and gallium nitride.

27. The device of claim 25, wherein a thickness of the channel is between about 0 and about 1 μm.

28. The device of claim 25, wherein a length of the channel is about 2 μm.

29. The device of claim 25, wherein the JFET shields the channels from the N-type anode region.

30. The device of claim 25, wherein the P-type layer is electrically connected to the P-type buried layer.

31. A method comprising:
providing an electronic system including nodes; and
operating, within the electronic system, a device electrically connected to the nodes and comprising:
an N-type substrate including first and second surfaces;
a P-type anode region being attached to the first surface of the N-type substrate;
a P-type buried layer positioned within the second surface of the N-type substrate;
a junction field-effect transistor (JFET) attached to a surface of the P-type buried layer and the second surface of the N-type substrate; and
a P-type layer positioned in the JFET and that, when active, forms a channel in the JFET that extends into the JFET between the P-type layer and the P-type buried layer.

32. The method of claim 31, wherein operating the device comprises using the device to limit current between the nodes and for fault detection.

33. The method of claim 31, wherein the system is a power distribution system.
